(19) United States
(12) Patent Application Publication
(10) Pub. No.: US 2002/0015286 A1
(43) Pub. Date: Feb. 7, 2002

(54) Temperature regulation apparatus for electrical box

(76) Inventors: Chien-Hsiung Wu, Taipei (TW); Shueh-Cheng Lu, Taipei (TW); Wan-Fu Kuo, Taipei (TW); Bin-Juine Huang, Taipei (TW)

Correspondence Address: PRO-TECHTOR INTERNATIONAL, 20775 Norada Court, Saratoga, CA, 95070-3018, US

(21) Appl. No.: 09/819,483

(22) Filed: Mar. 27, 2001

(30) Foreign Application Priority Data
Aug. 5, 2000 (TW) 89213631

(51) Int. Cl. H05K 7/20

(52) U.S. Cl. 361/695

(57) ABSTRACT

A temperature regulation apparatus is installed in an electrical box comprising a variety of electronic components on an internal board. The apparatus may be served as heat source if temperature sensed inside the box is below a predetermined value, or served as cold source if the sensed temperature is above another predetermined value. Hence, an optimal operating temperature for the electronic components is provided. Also, the apparatus is compact and durable.

### FIELD OF THE INVENTION

The present invention relates to thermoregulation and more particularly to a temperature regulation apparatus capable of activating a heating or cooling unit for electrical box.

### BACKGROUND OF THE INVENTION

The progress in the field of communications such as cellular phones, fixed network, wide bandwidth network, optical fiber, satellite communication, digital broadcasting, digital TV, or the like is significant. Conventionally, in the case of wireless wide bandwidth network, wireless wide bandwidth network relays are employed. One such relay is installed in electrical box. It is understood that the performance of electronic components may be adversely affected if the ambient temperature is not in the range of operating temperature. A conventional metal electrical box 70 shown in FIG. 4 comprises a board 71 on the rear and a variety of electronic components 72 and 73 on the board 71. However, the previous design did not provide a means to regulate temperature inside the box 70 (i.e., effectively dissipate heat out of the box 70). Thus, as stated above the performance of electronic components 72 and 73 may be adversely affected due to overheat, resulting in a mulfunction of the electrical box 70.

Thus, it is desirable to provide an improved temperature regulation apparatus for electrical box in order to overcome the above drawback of prior art.

### SUMMARY OF THE INVENTION

It is an object of the present invention to provide a temperature regulation apparatus mounted in an electrical box for regulating the interior temperature thereof.

It is another object of the present invention to provide a temperature regulation apparatus which is modularized, compact, and easy in installation.

It is still another object of the present invention to provide a temperature regulation apparatus capable of activating a heating unit when ambient temperature is relatively low or cooling unit when ambient temperature is relatively high, thereby providing a desirable operating environment for electronic components in an electrical box.

To achieve the above and other objects, the present invention provides a temperature regulation apparatus installed in an electrical box comprising a variety of electronic components on an internal board. The temperature regulation apparatus may be served as heat source if temperature sensed inside the box is below a predetermined value, or served as cold source if temperature sensed inside the box is above another predetermined value. Hence, an optimal operating temperature for the electronic components is provided. Also, the temperature regulation apparatus is compact and durable.

Preferably, the electrical box is insulated and comprises a pair of opposite mating rails (e.g., one is raised and the other is recessed) on one side for permitting the temperature regulation apparatus to slidingly secure thereto.

Preferably, the temperature regulation apparatus comprises a source device, a thermal dissipation member, an outer cover, a heat transfer member, a pair of first air circulating elements, a pair of second air circulating elements, and an inner cap wherein the source device is provided between the thermal dissipation member and the heat transfer member, the thermal dissipation member is provided at the outside of the source device and is covered by the outer cover, a fluid inlet and a fluid outlet are provided on the outer cover respectively, the first air circulating elements are functioned to drive air to flow into the fluid inlet and out of the fluid outlet respectively, the heat transfer member is provided within and covered by the outer cover, and the second air circulating elements are provided within the inner cap for driving air to flow into the inner cap and out of the inner cap respectively. The temperature regulation apparatus further comprises a drive circuit for activating the temperature regulation apparatus and a thermostat in association with the drive circuit for sensing temperature inside the electrical box.

In one aspect of the invention, the temperature regulation apparatus is mountable in an electrical box comprising a variety of advanced electronic components capable of operating in a high or low temperature environment by incorporating a source device served as cooling or heating unit.

The above and other objects, features and advantages of the present invention will become apparent from the following detailed description taken with the accompanying drawings.

### BRIEF DESCRIPTION OF THE DRAWINGS

FIG. 1 is an exploded perspective view of a temperature regulation apparatus, a source device, and an electrical box according to the invention;

FIG. 2 is an exploded view of the components shown in FIG. 1;

FIG. 3 is a partial cross-sectional view of FIG. 1; and

FIG. 4 is a perspective view of an open conventional electrical box.

### DETAILED DESCRIPTION OF THE PREFERRED EMBODIMENTS

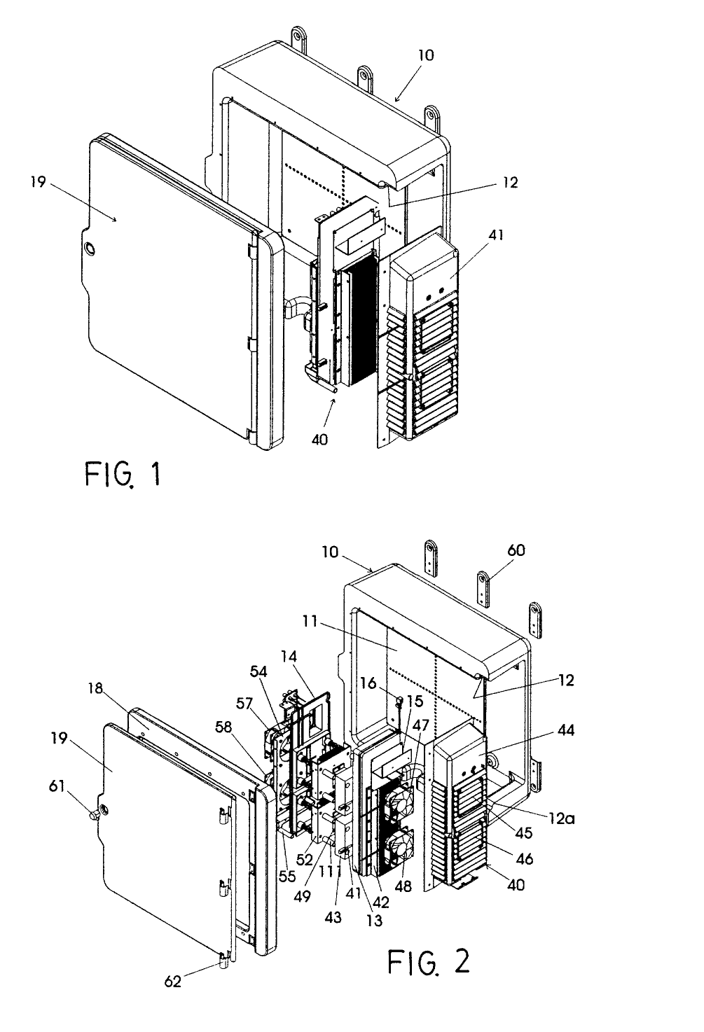

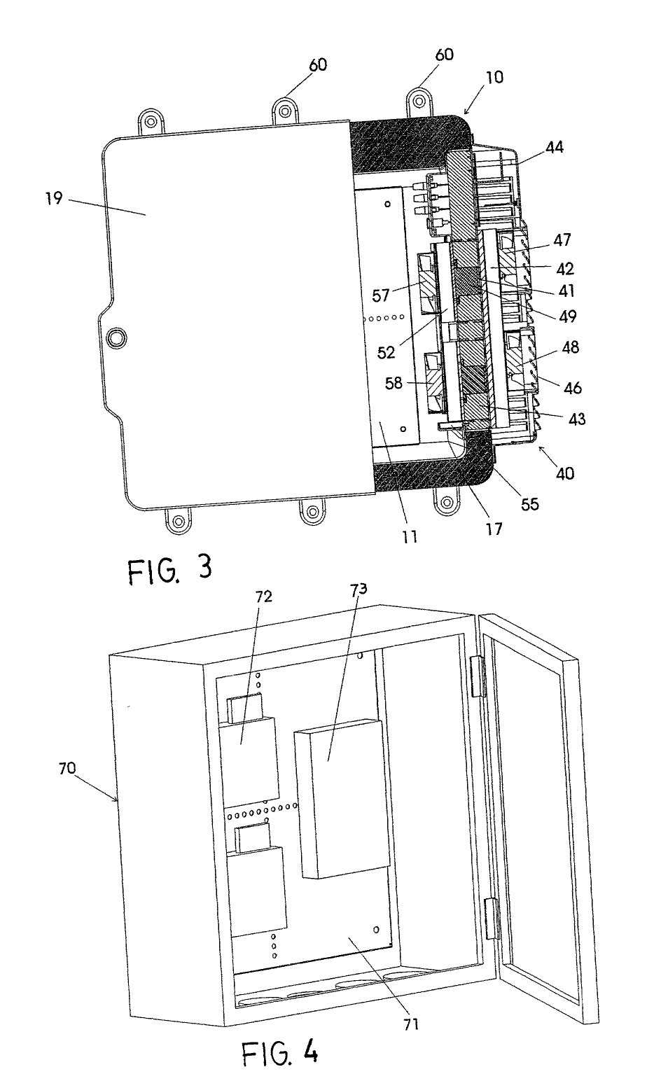

Referring to FIGS. 1 through 3, there is shown an electrical box 10 incorporating a temperature regulation apparatus 40 constructed in accordance with the invention. Electrical box 10 is substantially a parallelepiped and comprises an inner door 18 and an outer door 19 both for keeping the interior temperature of electrical box 10 for a relatively long period of time. Each door comprises a heat barrier element (not shown) stuffed with a heatproof material and a casing for enclosing the heat barrier element. Electrical box 10 further comprises a pair of opposite mating rails (e.g., one has a raised cross-section and the other has a recessed cross-section) 12 and 12a on one side for permitting temperature regulation apparatus 40 to slidingly secure thereto, a board 11 on the rear, a drive circuit 1 5 for activating temperature regulation apparatus 40, a variety of electronic components on the board 11, and a thermostat 16 in association with drive circuit 15 and for sensing temperature inside the electrical box 10. In one embodiment, drive circuit 15 is a programmable controller.

Temperature regulation apparatus 40 comprises a source device 41, a thermal dissipation member 42, an outer bracket 13, an outer cover 44, a heat barrier 43, a heat conduction element 49, a heat transfer member 52, an inner bracket 14, an inner cap 54, a drain pan 55, and other associated components. Each of above components is detailed below. Source device 41 is provided between thermal dissipation member 42 and heat transfer member 52 and is secured by outer bracket 13, inner bracket 14, and other fasteners. Thus, cold source generated from source device 41 may be uniformly distributed in the electrical box 10 through heat transfer member 52. Note that source device 41 may be served as heat source if current applied thereto is inverted with respect to polarity. Similarly, heat generated from source device 41 may be uniformly distributed in the electrical box 10 through heat transfer member 52. Thermal dissipation member 42 is in contact with the external side of source device 41. Thermal dissipation member 42 has a finned appearance for enhancing heat transfer efficiency. Thermal dissipation member 42 and air circulating elements (e.g., fans) 47 and 48 are covered by outer cover 44 so that heat from thermal dissipation member 42 may be quickly transferred to the external through air circulating elements 47 and 48. Hence, air may flow from outer cover 44 through inlet 46 and thermal dissipation member 42 to outlet 45 by the activation of air circulating elements 47 and 48. Heat transfer member 52 is provided at the internal side of source device 41. Heat conduction element 49 is sandwiched between heat transfer member 52 and source device 41. Heat transfer member 52 also has a finned appearance for enhancing heat transfer efficiency. Heat transfer member 52 is secured between inner bracket 14 and inner cap 54. Air circulating elements 57 and 58 are provided in inner cap 54 for enhancing air flow. Hence, cold source from heat transfer member 52 may be quickly transferred to the interior space of electrical box 10 through air circulating elements 57 and 58. Drain pan 55 is provided under heat transfer member 52 and is secured between inner bracket 14 and inner cap 54. Condensate from heat transfer member 52 are stored in drain pan 55. Hence, condensate may not overflow to damage electronic component on board 11. Heat barrier 43 is fitted between thermal dissipation member 42 and heat transfer member 52. Further, source device 41 is enclosed by heat barrier 43. Hence, cold source generated by source device 41 may not mix with heat source of thermal dissipation member 42 by the air therebetween. In other words, cold source generated by source device 41 may only transfer to outside through heat transfer member 52, while heat source generated by source device 41 may only transfer to outside through thermal dissipation member 42. A plurality of heat barrier elements 111 are coupled between thermal dissipation member 42 and heat transfer member 52 for supporting and fixing heat barrier 43. Heat barrier elements 111 are covered by heat barrier 43. In one embodiment, heat barrier element 111 is a bakelite.

The operation of the invention may be described as follows: When temperature inside the box 10 sensed by the thermostat 16 is above a first predetermined value, a signal is sent from thermostat 16 to the drive circuit 15. Then temperature regulation apparatus 40 is activated to generate cold source for decreasing temperature inside the box 10 by the enabled drive circuit 15. The temperature regulation apparatus 40 may be operated in a power saving mode when temperature inside box 10 has dropped to a second predetermined value which is smaller than the first predetermined value. Further, temperature regulation apparatus 40 may be shut down automatically by the drive circuit 15 when temperature regulation apparatus 40 has operated in the power saving mode for a predetermined period of time. Likewise, when temperature inside the box 10 sensed by the thermostat 16 is below a third predetermined value, a signal is sent from thermostat 16 to drive circuit 15. Then temperature regulation apparatus 40 is activated to generate heat source for increasing temperature inside the box 10 by the enabled drive circuit 15. The temperature regulation apparatus 40 may be operated in a power saving mode when temperature inside box 10 has risen to a fourth predetermined value which is larger than the third predetermined value. Further, temperature regulation apparatus 40 may be shut down automatically by the drive circuit 15 when temperature regulation apparatus 40 has operated in the power saving mode for a predetermined period of time.

In brief, the temperature regulation apparatus 40 is mountable in an electrical box 10 which comprises a variety of advanced electronic components operated in a high or low temperature environment. Hence, an electrical box 10 incorporating a temperature regulation apparatus 40 of the invention may be installed in office, house, factory, or any other suitable location. For achieving above purpose, a set of tabs 60 are provided on the edges of electrical box 10 so that user may drive fasteners through tabs 60 in order to secure the electrical box 10 to a desired place.

While the invention has been described by means of specific embodiments, numerous modifications and variations could be made thereto by those skilled in the art without departing from the scope and spirit of the invention set forth in the claims.

What is claimed is:

1. A temperature regulation apparatus installed in an electrical box including an internal board and a variety of electronic components on said board, said apparatus being served as a heat source if temperature sensed inside said box is below a first predetermined value, or served as a cold source if said sensed temperature is above a second predetermined value wherein said box is insulated and comprises a pair of opposite rails on one side for permitting said apparatus to secure thereto.

2. The apparatus of claim 1, wherein said box comprises an outer cover, an inner cap, and a heat barrier member sandwiched between said outer cover and said inner cap.

3. The apparatus of claim 1, comprising:
a source means;
a thermal dissipation member;
an outer cover having a fluid inlet and a fluid outlet;
a heat barrier;
a heat transfer member;
a heat conduction element;
a pair of first air circulating elements;
a pair of second air circulating elements;
an inner cap having a fluid inlet and a fluid outlet; and
a drain pan;
wherein said source means is between said thermal dissipation member and said heat transfer member, said thermal dissipation member is in contact with said external side of said source means, said heat transfer member is at said internal side of said source means and is in contact with said source means through said heat conduction element, said heat barrier is fitted between said source means and said heat transfer member and is in contact therewith, said outer cover covers said said thermal dissipation member and said first air circulating elements and is coupled to said box, said first air circulating elements are functioned to drive air to flow into said fluid inlet of said outer cover and out of said fluid outlet of said outer cover respectively, said inner cap covers said heat transfer member and are coupled to said second air circulating elements for driving air to flow into said fluid inlet of said inner cap and out of said fluid outlet of said inner cap respectively, and said drain pan is under said heat transfer member for storing condensate therefrom.

4. The apparatus of claim 3, wherein each of said first and said second air circulating elements is a fan.

5. The apparatus of claim 3, wherein said thermal dissipation member has a finned member enclosed therearound.

6. The apparatus of claim 3, wherein said heat transfer member has a finned member enclosed therearound.

7. The apparatus of claim 3, further comprising a drive circuit for activating said apparatus to generate heat or cold.

8. The apparatus of claim 3, further comprising a thermostat for activating said drive circuit.

9. The apparatus of claim 1, wherein said apparatus are operable to slidingly move along said pair of opposite rails.

10. The apparatus of claim 9, wherein said pair of opposite rails are matingly provided.

11. The apparatus of claim 10, wherein one of rails has a raised cross-section and said other has a recessed cross-section.

12. The apparatus of claim 2, further comprising an inner door and an outer door both for keeping said interior temperature of said box for a predetermined period of time.

13. The apparatus of claim 12, wherein each of said doors comprises a heat barrier element and a casing for enclosing said heat barrier element.

14. The apparatus of claim 2, wherein said heat barrier member is stuffed with a heatproof material.

15. The apparatus of claim 1, further comprising a plurality of tabs on said edges of said box for fastening to a predetermined position.

16. The apparatus of claim 3, further comprising a plurality of heat barrier means coupled between said thermal dissipation member and said heat transfer member for supporting.

17. The apparatus of claim 16, wherein each of said heat barrier means is a bakelite.

18. The apparatus of claim 3, wherein said heat barrier is stuffed with a heatproof material.

19. The apparatus of claim 3, wherein said heat conduction element is formed of a thermal conductivity material.

20. The apparatus of claim 13, wherein said heat barrier element is stuffed with a heatproof material.
